(19) United States
(12) Patent Application Publication
(10) Pub. No.: US 2025/0391771 A1
(43) Pub. Date: Dec. 25, 2025

(54) INTEGRATED CIRCUIT INCLUDING SIGNAL TRANSFER FILLER CELL

(71) Applicant: SAMSUNG ELECTRONICS CO., LTD., Suwon-si (KR)

(72) Inventors: Jaeha LEE, Suwon-si (KR); Huijae LIM, Suwon-si (KR); Subin Jin, Suwon-si (KR); Unseon CHEON, Suwon-si (KR)

(73) Assignee: SAMSUNG ELECTRONICS CO., LTD., Suwon-si (KR)

(21) Appl. No.: 19/020,004

(22) Filed: Jan. 14, 2025

(30) Foreign Application Priority Data
Jun. 21, 2024 (KR) 10-2024-0081374

(51) Int. Cl. H01L 23/528; H10D 89/10

(52) U.S. Cl. CPC H01L 23/5286; H10D 89/10

(57) ABSTRACT

An integrated circuit includes a first standard cell including a first plurality of patterns extending in a first direction, the first standard cell having a first pitch; a second standard cell including a second plurality of patterns extending in the first direction, the second standard cell having a second pitch different from the first pitch, the second standard cell spaced apart from the first standard cell in the first direction; a signal transfer filler cell between the first standard cell and the second standard cell, the signal transfer filler cell including at least one jog pattern connecting one pattern in the first plurality of patterns to one pattern in the second plurality of patterns; a first power rail having a first width in a second direction perpendicular to the first direction above the first standard cell; and a second power rail having a second width different from the first width.

### CROSS-REFERENCE TO RELATED APPLICATION

This application is based on and claims priority under 35 U.S.C. § 119 to Korean Patent Application No. 10-2024-0081374, filed on Jun. 21, 2024, in the Korean Intellectual Property Office, the disclosure of which is incorporated by reference herein in its entirety.

### BACKGROUND

Integrated circuits may include a plurality of function blocks, which may be designed according to heterogeneous architectures. To use heterogeneous structures, a different architecture was applied to each block, and blocks were combined with each other at a block level by using block termination to combine these function blocks with each other. Each function block may include a plurality of standard cells. Standard cells included in one function block are usually designed according to the same architecture. However, with the diversification of the architecture of standard cells, in order to optimize the power performance area (PPA) of an integrated circuit, it is required to design standard cells included in one function block according to heterogeneous architectures.

### SUMMARY

The inventive concept provides an integrated circuit including a signal transfer filler cell connecting standard cells, which have heterogeneous architectures, to each other.

According to an aspect of the disclosure, an integrated circuit includes: a first standard cell including a first set of a plurality of patterns extending in a first direction, the first standard cell having a first pitch; a second standard cell includes a second set of a plurality of patterns extending in the first direction, the second standard cell having a second pitch different from the first pitch, the second standard cell spaced apart from the first standard cell in the first direction; a signal transfer filler cell between the first standard cell and the second standard cell, the signal transfer filler cell including at least one jog pattern connecting one pattern in the first set of the plurality of patterns to one pattern in the second set of the plurality of patterns; a first power rail having a first width in a second direction perpendicular to the first direction above the first standard cell; and a second power rail having a second width different from the first width in the second direction above the second standard cell.

According to an aspect of the disclosure, an integrated circuit includes: a first standard cell including an N-track structure; a second standard cell including an M-track structure, the second standard cell spaced apart from the first standard cell in a first direction; a signal transfer filler cell between the first standard cell and the second standard cell; a first power rail connected to the first standard cell, the first power rail having a first width in a second direction perpendicular to the first direction; a second power rail connected to the second standard cell, the second power rail having a second width different from the first width in the second direction; N patterns arranged above the first standard cell according to the N-track structure; M patterns arranged above the second standard cell according to the M-track structure; and at least one jog pattern above the signal transfer filler cell, the at least one jog pattern connecting one pattern of the N patterns to one pattern of the M patterns, wherein N and M are different positive integers of at least two.

According to an aspect of the disclosure, an integrated circuit includes: a first standard cell group; a second standard cell group spaced apart from the first standard cell group in a first direction; and a signal transfer filler cell group between the first standard cell group and the second standard cell group, wherein the first standard cell group includes a plurality of first standard cells arranged in a second direction perpendicular to the first direction, each first standard cell including an N-track structure, wherein the second standard cell group includes a plurality of second standard cells arranged in the second direction, each second standard cell including an M-track structure, wherein the signal transfer filler cell group includes a plurality of signal transfer filler cells arranged in the second direction, each signal transfer filler cell including at least one jog pattern, wherein the plurality of signal transfer filler cells each have a same shape, and wherein N and M are positive integers of at least two.

### BRIEF DESCRIPTION OF DRAWINGS

Embodiments will be more clearly understood from the following detailed description taken in conjunction with the accompanying drawings in which:

FIG. 1 illustrates a layout of an integrated circuit according to one or more embodiments;

FIG. 2 illustrates a signal transfer filler cell according to one or more embodiments;

FIGS. 3A to 3F illustrate signal transfer filler cells according to some embodiments;

FIGS. 4A to 4F illustrate signal transfer filler cells according to some embodiments;

FIGS. 5A and 5B illustrate integrated circuits according to some embodiments;

FIG. 6 illustrates an integrated circuit according to one or more embodiments;

FIG. 7 illustrates an integrated circuit according to one or more embodiments;

FIGS. 8A to 8F illustrate signal transfer filler cells according to some embodiments;

FIGS. 9A to 9C illustrate signal transfer filler cells according to some embodiments;

FIGS. 10A to 10D illustrate devices according to some embodiments;

FIG. 11 is a flowchart of a method of manufacturing an integrated circuit, according to one or more embodiments;

FIG. 12 is a block diagram of a system-on-chip according to one or more embodiments; and

FIG. 13 is a block diagram of a computing system including memory storing a program, according to one or more embodiments.

### DETAILED DESCRIPTION

Hereinafter, embodiments will be described in detail with reference to the accompanying drawings. In the drawings, like reference characters denote like elements, and redundant descriptions thereof will be omitted.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

According to one or more embodiments, an X-axis direction may be referred to as a first horizontal direction or a first direction, a Y-axis direction may be referred to as a second horizontal direction or a second direction, and a Z-axis direction may be referred to as a vertical direction. A plane defined by an X-axis and a Y-axis may be referred to as a horizontal plane. An element positioned in a +Z-axis direction relative to another element may be considered as being above the other element. An element positioned in a −Z-axis direction relative to another element may be considered as being below the other element.

An integrated circuit (IC) may be designed by arranging a plurality of standard cells. A standard cell may be a layout unit in an IC and may be referred to as a “cell” according to embodiments. A standard cell may be designed to include a plurality of transistors to perform a predefined function. In a standard cell method, standard cells having various functions are prepared in advance and combined to design a dedicated large-scale IC tailored to a customer's or user's specification. Standard cells may be designed and verified in advance and registered in a standard cell library. An IC may be designed by performing logical design combining standard cells by using computer aided design (CAD), placement, and routing.

In one or more examples, standard-cell methodology may be a method of designing application-specific integrated circuits (ASICs) with mostly digital-logic features. Standard-cell methodology is an example of design abstraction, whereby a low-level very-large-scale integration (VLSI) layout is encapsulated into an abstract logic representation (such as a NAND gate). Cell-based methodology makes it possible for one designer to focus on the high-level (logical function) aspect of digital design, while another designer focuses on the implementation (physical) aspect. Along with semiconductor manufacturing advances, standard-cell methodology has helped designers scale ASICs from comparatively simple single-function ICs (of several thousand gates), to complex multi-million gate system-on-a-chip (SoC) devices.

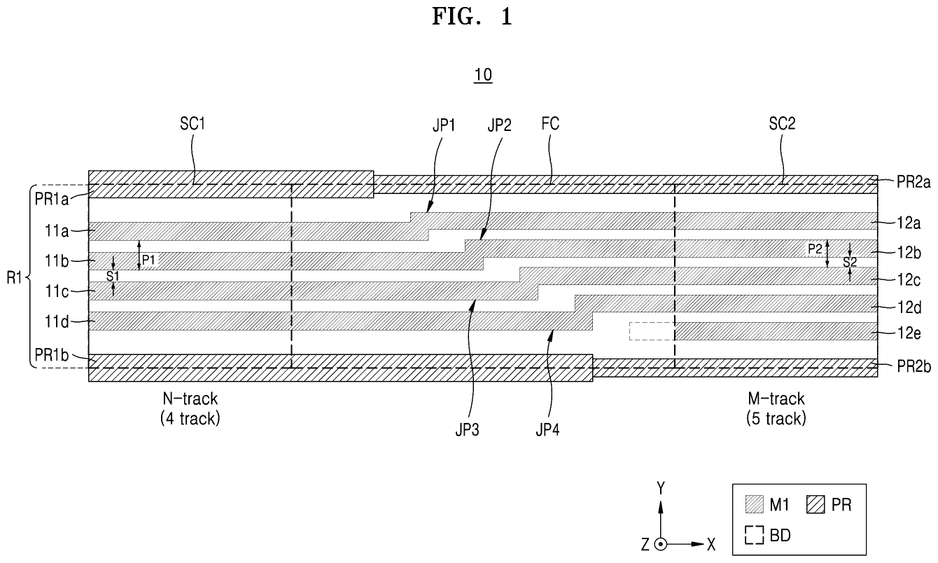

FIG. 1 illustrates a layout of an IC 10 according to one or more embodiments.

Referring to FIG. 1, the IC 10 may include a first standard cell SC1, a second standard cell SC2, and a signal transfer filler cell FC. The first standard cell SC1 may be spaced apart from the second standard cell SC2 in the first direction X. The signal transfer filler cell FC may be between the first standard cell SC1 and the second standard cell SC2. For example, the first standard cell SC1, the signal transfer filler cell FC, and the second standard cell SC2 may be arranged in a first row R1 in the first direction X. Accordingly, the first standard cell SC1, the signal transfer filler cell FC, and the second standard cell SC2 may have the same cell height. For example, the first standard cell SC1, the signal transfer filler cell FC, and the second standard cell SC2 may be arranged in the same logic block or the same function block. As understood by one of ordinary skill in the art, the embodiments are not limited to this configuration. For example, the first standard cell SC1 and the second standard cell SC2 may have different heights.

The first and second standard cells SC1 and SC2 may be designed based on heterogeneous architectures, respectively. For example, an architecture may include a track number or a metal track number, but the embodiments of the present disclosure are not limited thereto. In one or more embodiments, the first standard cell SC1 may be designed according to a first architecture, and a metal track number of the first architecture may be N. The second standard cell SC2 may be designed according to a second architecture, and a metal track number of the second architecture may be M. In one or more examples, N and M may be different positive integers of at least 2. The first standard cell SC1 may have an N-track structure. For example, N may be 4, but the embodiments of the present disclosure are not limited thereto. The second standard cell SC2 may have an M-track structure. For example, M may be 5, but the embodiments of the present disclosure are not limited thereto. In one or more examples, M may be less than N.

The first standard cell SC1 may include first to fourth metal patterns or first to fourth patterns 11a to 11d. The first to fourth patterns 11a to 11d may extend in the first direction X and have a first pitch P1. The first to fourth patterns 11a to 11d may be spaced apart from each other by a first spacing S1 in the second direction Y. The second standard cell SC2 may include first to fifth metal patterns or first to fifth patterns 12a to 12e. The first to fifth patterns 12a to 12e may extend in the first direction X and have a second pitch P2. The first to fifth patterns 12a to 12e may be spaced apart from each other by a second spacing S2 in the second direction Y. In one or more examples, a pitch may refer to a distance between two patterns in a cell. In one or more examples, each pattern in a cell may have the same pitch. However, as understood by one of ordinary skill in the art, patterns within a same cell may have different pitches.

In one or more embodiments, the first pitch P1 may be different from the second pitch P2. For example, the first pitch P1 may be greater than the second pitch P2. In one or more embodiments, the first spacing S1 may be different from the second spacing S2. For example, the first spacing S1 may be greater than the second spacing S2. For example, the first to fourth patterns 11a to 11d and the first to fifth patterns 12a to 12e may be formed as unidirectional patterns. For example, the first to fourth patterns 11a to 11d may not be aligned with the first to fifth patterns 12a to 12e.

The first to fourth patterns 11a to 11d and the first to fifth patterns 12a to 12e may be at the same level. For example, the first to fourth patterns 11a to 11d and the first to fifth patterns 12a to 12e may be included in a first metal layer M1. For example, the first metal layer M1 may be arranged above the first standard cell SC1, the signal transfer filler cell FC, and the second standard cell SC2 in the vertical direction Z. However, the embodiments of the present disclosure are not limited thereto. The first metal layer M1 may be arranged below the first standard cell SC1, the signal transfer filler cell FC, and the second standard cell SC2 in the vertical direction Z.

For example, four metal tracks (e.g., the first to fourth patterns 11a to 11d), may be routed above the first standard cell SC1, and five metal tracks (e.g., the first to fifth patterns 12a to 12e), may be routed above the second standard cell SC2. As described above, when the numbers of patterns routed above the first and second standard cells SC1 and SC2, which are arranged in the same row (e.g., the first row R1) of the same logical block, are different, a connection between the patterns may not be easy to implement, and accordingly, it may be difficult to secure the electrical characteristics of signals transferred through the patterns.

However, according to the present embodiment, the signal transfer filler cell FC may be provided between the first standard cell SC1 and the second standard cell SC2. In one or more examples, the signal transfer filler cell FC may include a plurality of jogging patterns or jog patterns (e.g., JP1 to JP4) for signal transfer between the first and second standard cells SC1 and SC2. For example, the jog patterns (JP1 to JP4) may include a first jog pattern JP1 connecting the first pattern 11a to the first pattern 12a, a second jog pattern JP2 connecting the second pattern 11b to the second pattern 12b, a third jog pattern JP3 connecting the third pattern 11c to the third pattern 12c, and a fourth jog pattern JP4 connecting the fourth pattern 11d to the fourth pattern 12d. For example, the first to fourth jog patterns JP1 to JP4 may have the same pattern shape. According to one or more embodiments, a “signal transfer filler cell” may be referred to as a “track transfer filler cell” or a “filler cell”.

In one or more examples, a jogging pattern or a jog pattern may be defined as a conductive pattern rather than a unidirectional pattern. For example, a jog pattern may be implemented using bidirectional patterns. For example, a jog pattern may have a bent shape, an L-shape, or a Z-shape. For example, a jog pattern may include a first portion extending in the first direction X and a second portion extending in the first direction X. The first portion may be in contact with or connected to the second portion. For example, a jog pattern may include a first portion extending in the first direction X, a second portion extending in the first direction X, a third portion extending in the second direction Y. The first portion may be connected to the second portion by the third portion. Although FIG. 1 illustrates jog patterns JP1-JP4 where one portion (e.g., first portion) is below another portion (e.g., second portion), the embodiments are not limited to this configuration. For example, a jog pattern may include one portion (e.g., first portion) that is raised above another portion (e.g., second portion).

The IC 10 may further include power rails PR. For example, the power rails PR may be above the first standard cell SC1, the signal transfer filler cell FC, and the second standard cell SC2 in the vertical direction Z. However, the embodiments of the present disclosure are not limited thereto. The power rails PR may be below the first standard cell SC1, the signal transfer filler cell FC, and the second standard cell SC2 in the vertical direction Z. For example, the power rails PR may be at the same levels as the first to fourth patterns 11a to 11d and the first to fifth patterns 12a to 12e. The power rails PR may be included in the first metal layer M1.

The power rails PR may include first power rails PR1a and PR1b above the first standard cell SC1 and second power rails PR2a and PR2b above the second standard cell SC2. For example, the first power rails PR1a and PR1b may respectively overlap the top cell boundary and the bottom cell boundary of the first standard cell SC1. For example, the second power rails PR2a and PR2b may respectively overlap the top cell boundary and the bottom cell boundary of the second standard cell SC2. For example, the first and second power rails PR1a and PR2a may receive a first supply voltage (e.g., a power supply voltage (VDD)). For example, the first and second power rails PR1b and PR2b may receive a second supply voltage (e.g., a ground voltage (VSS)).

In one or more embodiments, the first and second power rails PR1a and PR2a may have different widths in the second direction Y. For example, the first and second power rails PR1a and PR2a may be routed according to an adjacent jog pattern (e.g., the first jog pattern JP1). For example, based on the first jog pattern JP1, the lengths of the first and second power rails PR1a and PR2a may change on the top of the signal transfer filler cell FC. In one or more embodiments, the first and second power rails PR1b and PR2b may have different widths in the second direction Y. For example, the first and second power rails PR1b and PR2b may be routed according to an adjacent jog pattern (e.g., the fourth jog pattern JP4). For example, based on the fourth jog pattern JP4, the lengths of the first and second power rails PR1b and PR2b may change on the top of the signal transfer filler cell FC.

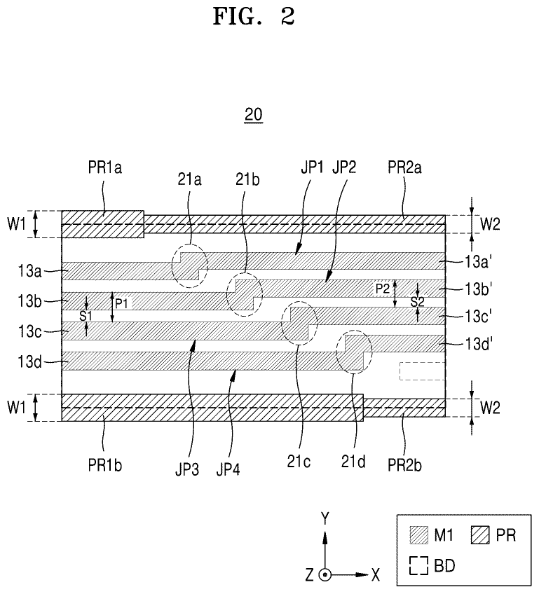

FIG. 2 illustrates a signal transfer filler cell 20 according to one or more embodiments.

Referring to FIGS. 1 and 2, the signal transfer filler cell 20 may correspond to the signal transfer filler cell FC in FIG. 1. The signal transfer filler cell 20 may be between the first standard cell SC1 having a 4-track structure and the second standard cell SC2 having a 5-track structure. The signal transfer filler cell 20 may include signal transfer patterns respectively connecting four metal tracks (e.g., the first to fourth patterns 11a to 11d) of the first standard cell SC1 to four metal tracks among five metal tracks (e.g., the first to fifth patterns 12a to 12e) of the second standard cell SC2. The signal transfer patterns may include the first to fourth jog patterns JP1 to JP4.

The first power rail PR1a may have a first width W1 in the second direction Y. The second power rail PR2a may have a second width W2 in the second direction Y, the second width W2 being different from the first width W1. For example, the first width W1 may be greater than the second width W2. Similarly, the first power rail PR1b may have the first width W1 in the second direction Y. The second power rail PR2b may have the second width W2 in the second direction Y, the second width W2 being different from the first width W1. As such, above the signal transfer filler cell 20, the first and second power rails PR1a and PR2a overlapping the top cell boundary may have different widths and the first and second power rails PR1b and PR2b overlapping the bottom cell boundary may have different widths. Accordingly, the first to fourth jog patterns JP1 to JP4 at the same level as the first and second power rails PR1a, PR1b, PR2a, and PR2b may be required to be arranged considering design rules such as the minimum spacing between patterns.

The first jog pattern JP1 may include a first portion 13a, which is connected to the first pattern 11a and extends in the first direction X, and a second portion 13a′, which is connected to the first pattern 12a and extends in the first direction X. The first portion 13a and the second portion 13a′ of the first jog pattern JP1 may not be aligned with each other. A region in which the first portion 13a is in contact with the second portion 13a′ may be referred to as a junction region 21a. According to one or more embodiments, the first jog pattern JP1 may further include a third portion extending in the second direction Y in the junction region 21a.

The second jog pattern JP2 may include a first portion 13b, which is connected to the second pattern 11b and extends in the first direction X, and a second portion 13b′, which is connected to the second pattern 12b and extends in the first direction X. The first portion 13b and the second portion 13b′ of the second jog pattern JP2 may not be aligned with each other. A region in which the first portion 13b is in contact with the second portion 13b′ may be referred to as a junction region 21b. According to one or more embodiments, the second jog pattern JP2 may further include a third portion extending in the second direction Y in the junction region 21b.

The third jog pattern JP3 may include a first portion 13c, which is connected to the third pattern 11c and extends in the first direction X, and a second portion 13c′, which is connected to the third pattern 12c and extends in the first direction X. The first portion 13c and the second portion 13c′ of the third jog pattern JP3 may not be aligned with each other. A region in which the first portion 13c is in contact with the second portion 13c′ may be referred to as a junction region 21c. According to one or more embodiments, the third jog pattern JP3 may further include a third portion extending in the second direction Y in the junction region 21c.

The fourth jog pattern JP4 may include a first portion 13d, which is connected to the fourth pattern 11d and extends in the first direction X, and a second portion 13d′, which is connected to the fourth pattern 12d and extends in the first direction X. The first portion 13d and the second portion 13d′ of the fourth jog pattern JP4 may not be aligned with each other. A region in which the first portion 13d is in contact with the second portion 13d′ may be referred to as a junction region 21d. According to one or more embodiments, the fourth jog pattern JP4 may further include a third portion extending in the second direction Y in the junction region 21d.

For example, the first portions 13a to 13d may have different lengths in the first direction X, and the second portions 13a′ to 13d′ may have different lengths in the first direction X. For example, a first spacing S1 between the first portions 13b and 13c may be different from a second spacing S2 between the second portions 13b′ and 13c′. For example, the first spacing S1 may be greater than the second spacing S2. For example, the spacing between the first to fourth jog patterns JP1 to JP4 and the power rails PR in the signal transfer filler cell 20 may be greater than or equal to the second spacing S2. For example, the spacing between two adjacent junction regions among the junction regions 21a to 21d may be greater than the second spacing S2. For example, the heights of the junction regions 21a to 21d in the second direction Y may be substantially the same, but the embodiments of the present disclosure are not limited thereto. In one or more examples, the junction regions 21a-21d may be spaced apart from each other by an equal distance. In one or more examples, a distance between junction region 21a and 21b may be different from a distance between junction region 21b and 21c. In one or more example, each junction region may have a same height. However, as understood by one of ordinary skill in the art, the embodiments are not limited to this configuration. For example, one or more of the junction regions may have different heights.

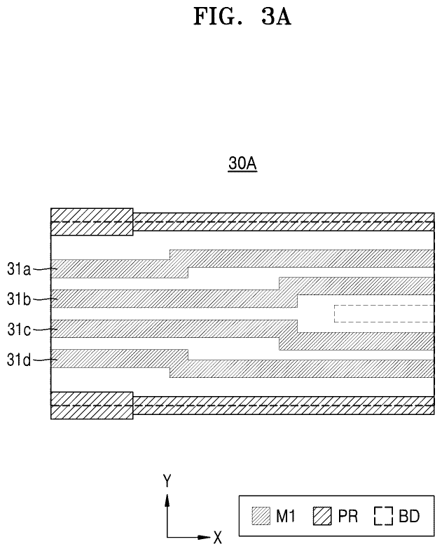

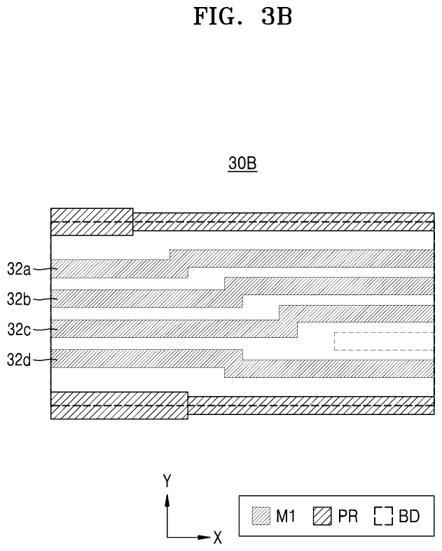

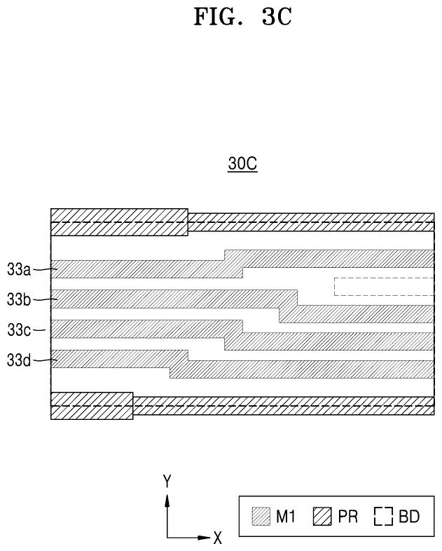

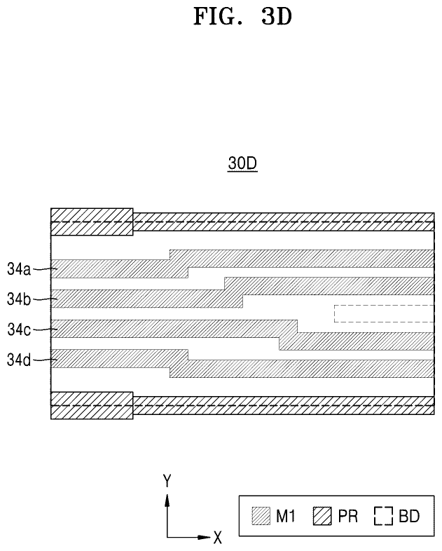

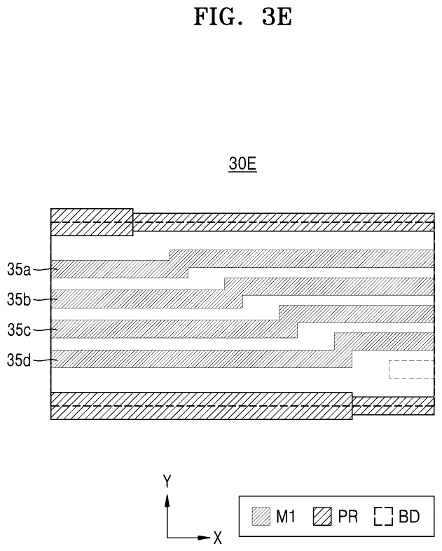

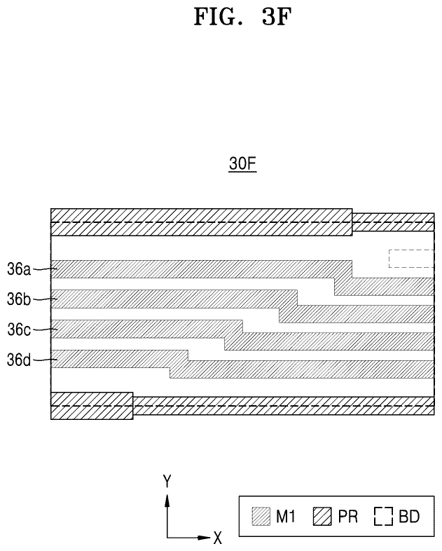

In some embodiments, the signal transfer filler cell 20 may further include a pattern, which is connected to the fifth pattern 12e and extends in the first direction X, but this pattern may not be connected to one of the first to fourth patterns 11a to 11d of the first standard cell SC1. In some embodiments, the signal transfer filler cell 20 may not include at least one of the first to fourth jog patterns JP1 to JP4, and only some of the first to fourth patterns 11a to 11d of the first standard cell SC1 may be connected to the second standard cell SC2. Furthermore, the placement and wiring of the first to fourth jog patterns JP1 to JP4 may vary with embodiments. This is described below with reference to FIGS. 3A to 3F.

FIGS. 3A to 3F illustrate signal transfer filler cells according to some embodiments. In one or more examples, a signal transfer filler cell is referred to as a filler cell.

Referring to FIGS. 1 and 3A, a filler cell 30A may include jog patterns 31a to 31d respectively connected to first, second, fourth, and fifth patterns 12a, 12b, 12d, and 12e of the second standard cell SC2. In one or more examples, the filler cell 30A may include the jog pattern 31a connecting the first pattern 11a to the first pattern 12a, the jog pattern 31b connecting the second pattern 11b to the second pattern 12b, the jog pattern 31c connecting the third pattern 11c to the fourth pattern 12d, and the jog pattern 31d connecting the fourth pattern 11d to the fifth pattern 12e.

In one or more examples, the jog pattern 31b may have a form in which the jog pattern 31a is shifted in the first direction X (e.g., the jog patterns 31b and 31a have a same shape, but the jog pattern 31a is shifted in the X direction compared to the jog pattern 31b). In one or more examples, the jog pattern 31c may have a form symmetrical with the jog pattern 31b in the second direction Y. In one or more examples, the jog pattern 31d may have a form symmetrical with the jog pattern 31a in the second direction Y. In this case, the spacing between adjacent jog patterns among the jog patterns 31a to 31d may be greater than or equal to the second spacing S2.

Referring to FIGS. 1 and 3B, a filler cell 30B may include jog patterns 32a to 32d respectively connected to first, second, third, and fifth patterns 12a, 12b, 12c, and 12e of the second standard cell SC2. In one or more examples, the filler cell 30B may include the jog pattern 32a connecting the first pattern 11a to the first pattern 12a, the jog pattern 32b connecting the second pattern 11b to the second pattern 12b, the jog pattern 32c connecting the third pattern 11c to the third pattern 12c, and the jog pattern 32d connecting the fourth pattern 11d to the fifth pattern 12e.

In one or more examples, the jog pattern 32b may have a form in which the jog pattern 32a is shifted in the first direction X (e.g., the jog patterns 32b and 32a have a same shape, but the jog pattern 32a is shifted in the X direction compared to the jog pattern 32b). In one or more examples, the jog pattern 32c may have a form in which the jog pattern 32b is shifted in the first direction X (e.g., the jog patterns 32c and 32b have a same shape, but the jog pattern 32b is shifted in the X direction compared to the jog pattern 32c). In one or more examples, the jog pattern 32d may have a form symmetrical with the jog pattern 32b in the second direction Y. In this case, the spacing between adjacent jog patterns among the jog patterns 32a to 32d may be greater than or equal to the second spacing S2.

Referring to FIGS. 1 and 3C, a filler cell 30C may include jog patterns 33a to 33d respectively connected to first, third, fourth, and fifth patterns 12a, 12c, 12d, and 12e of the second standard cell SC2. In one or more examples, the filler cell 30C may include the jog pattern 33a connecting the first pattern 11a to the first pattern 12a, the jog pattern 33b connecting the second pattern 11b to the third pattern 12c, the jog pattern 33c connecting the third pattern 11c to the fourth pattern 12d, and the jog pattern 33d connecting the fourth pattern 11d to the fifth pattern 12e.

In one or more examples, the jog pattern 33c may have a form in which the jog pattern 33d is shifted in the first direction X (e.g., the jog patterns 33c and 33d have a same shape, but the jog pattern 33c is shifted in the X direction compared to the jog pattern 33d). In one or more examples, the jog pattern 33b may have a form in which the jog pattern 33c is shifted in the first direction X. In one or more examples, the jog pattern 33a may have a form symmetrical with the jog pattern 33c in the second direction Y. In this case, the spacing between adjacent jog patterns among the jog patterns 33a to 33d may be greater than or equal to the second spacing S2.

Referring to FIGS. 1 and 3D, a filler cell 30D may include jog patterns 34a to 34d respectively connected to first, second, fourth, and fifth patterns 12a, 12b, 12d, and 12e of the second standard cell SC2. In one or more examples, the filler cell 30D may include the jog pattern 34a connecting the first pattern 11a to the first pattern 12a, the jog pattern 34b connecting the second pattern 11b to the second pattern 12b, the jog pattern 34c connecting the third pattern 11c to the fourth pattern 12d, and the jog pattern 34d connecting the fourth pattern 11d to the fifth pattern 12e.

In one or more examples, the jog pattern 34b may have a form in which the jog pattern 34a is shifted in the first direction X (e.g., the jog patterns 34b and 34a have a same shape, but the jog pattern 34a is shifted in the X direction compared to the jog pattern 34b). In one or more examples, the jog pattern 34c may have a form in which the jog pattern 34d is shifted in the first direction X (e.g., the jog patterns 34c and 34d have a same shape, but the jog pattern 34c is shifted in the X direction compared to the jog pattern 34d). In one or more examples, the jog pattern 34d may have a form symmetrical with the jog pattern 34a in the second direction Y. In this case, the spacing between adjacent jog patterns among the jog patterns 34a to 34d may be greater than or equal to the second spacing S2.

Referring to FIGS. 1 and 3E, a filler cell 30E may include jog patterns 35a to 35d respectively connected to first, second, third, and fourth patterns 12a, 12b, 12c, and 12d of the second standard cell SC2. In one or more examples, the filler cell 30E may include the jog pattern 35a connecting the first pattern 11a to the first pattern 12a, the jog pattern 35b connecting the second pattern 11b to the second pattern 12b, the jog pattern 35c connecting the third pattern 11c to the third pattern 12c, and the jog pattern 35d connecting the fourth pattern 11d to the fourth pattern 12d.

In one or more examples, the jog pattern 35b may have a form in which the jog pattern 35a is shifted in the first direction X (e.g., the jog patterns 35b and 35a have a same shape, but the jog pattern 35a is shifted in the X direction compared to the jog pattern 35b). In one or more examples, the jog pattern 35c may have a form in which the jog pattern 35b is shifted in the first direction X (e.g., the jog patterns 35c and 35b have a same shape, but the jog pattern 35b is shifted in the X direction compared to the jog pattern 35c). In one or more examples, the jog pattern 35d may have a form in which the jog pattern 35c is shifted in the first direction X (e.g., the jog patterns 35d and 35c have a same shape, but the jog pattern 35c is shifted in the X direction compared to the jog pattern 35d). In this case, the spacing between adjacent jog patterns among the jog patterns 35a to 35d may be greater than or equal to the second spacing S2.

Referring to FIGS. 1 and 3F, a filler cell 30F may include jog patterns 36a to 36d respectively connected to second to fifth patterns 12b, 12c, 12d, and 12e of the second standard cell SC2. In one or more examples, the filler cell 30F may include the jog pattern 36a connecting the first pattern 11a to the second pattern 12b, the jog pattern 36b connecting the second pattern 11b to the third pattern 12c, the jog pattern 36c connecting the third pattern 11c to the fourth pattern 12d, and the jog pattern 36d connecting the fourth pattern 11d to the fifth pattern 12e.

In one or more examples, the jog pattern 36c may have a form in which the jog pattern 36d is shifted in the first direction X (e.g., the jog patterns 36c and 36d have a same shape, but the jog pattern 36c is shifted in the X direction compared to the jog pattern 36d). In one or more examples, the jog pattern 36b may have a form in which the jog pattern 36c is shifted in the first direction X (e.g., the jog patterns 36b and 36c have a same shape, but the jog pattern 36b is shifted in the X direction compared to the jog pattern 36c). In one or more examples, the jog pattern 36a may have a form in which the jog pattern 36b is shifted in the first direction X (e.g., the jog patterns 36a and 36b have a same shape, but the jog pattern 36a is shifted in the X direction compared to the jog pattern 36b). In this case, the spacing between adjacent jog patterns among the jog patterns 36a to 36d may be greater than or equal to the second spacing S2.

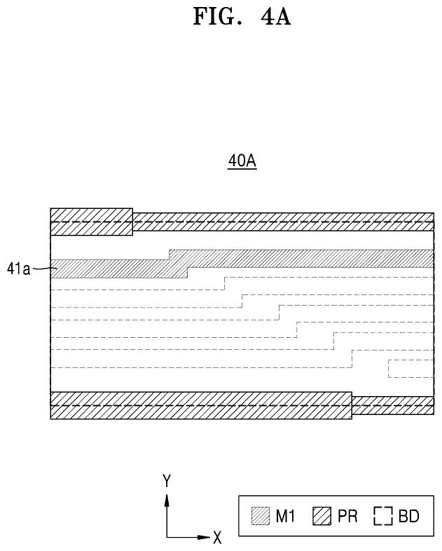

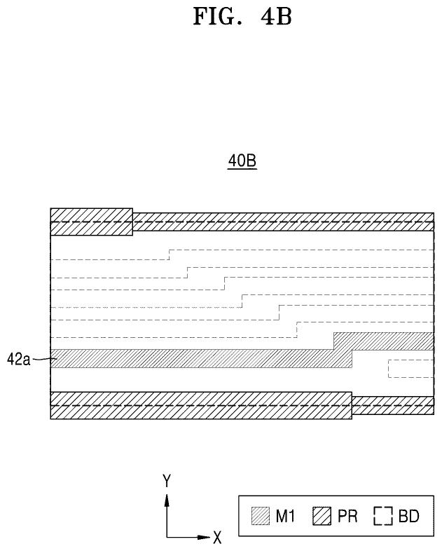

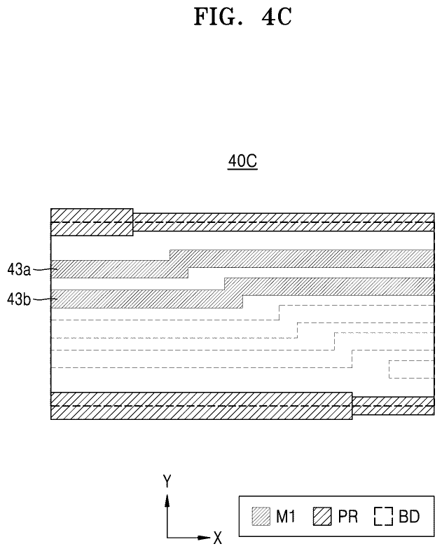

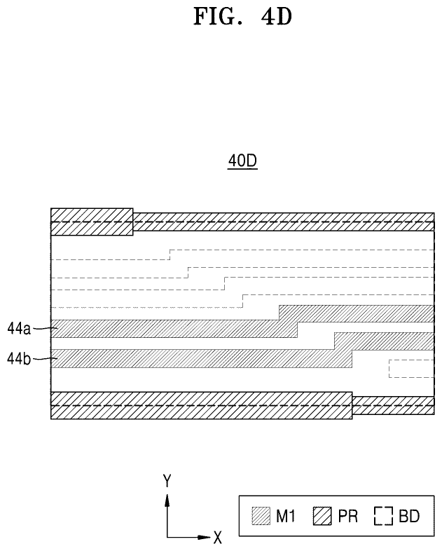

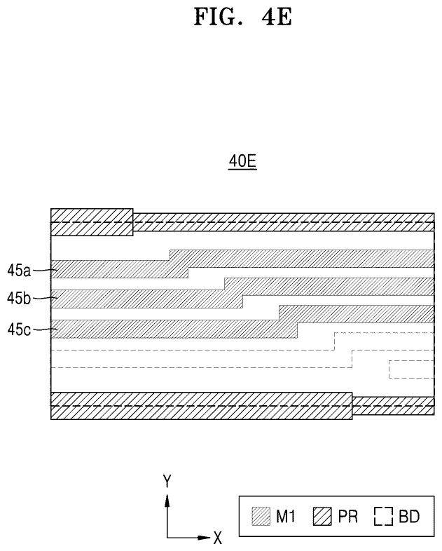

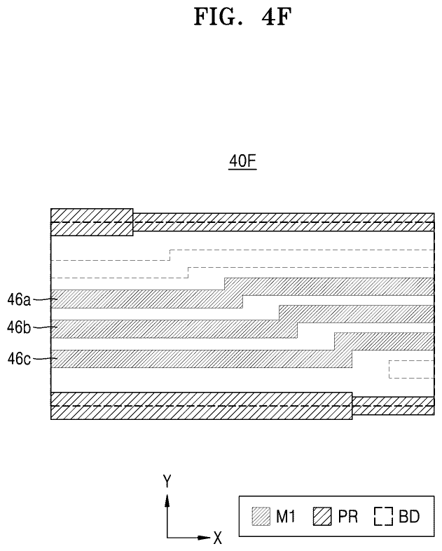

FIGS. 4A to 4F illustrate filler cells according to some embodiments.

Referring to FIGS. 1, 4A, and 4B, a filler cell 40A may include a jog pattern 41a. The jog pattern 41a may connect the first pattern 11a of the first standard cell SC1 to the first pattern 12a of the second standard cell SC2. A filler cell 40B may include a jog pattern 42a. The jog pattern 42a may connect the fourth pattern 11d of the first standard cell SC1 to the fourth pattern 12d of the second standard cell SC2. As described above, each of the filler cells 40A and 40B may include one jog pattern. In this case, patterns connected to both sides of one jog pattern may vary with embodiments.

Referring to FIGS. 1, 4C, and 4D, a filler cell 40C may include jog patterns 43a and 43b. The jog pattern 43a may connect the first pattern 11a of the first standard cell SC1 to the first pattern 12a of the second standard cell SC2, and the jog pattern 43b may connect the second pattern 11b of the first standard cell SC1 to the second pattern 12b of the second standard cell SC2. The filler cell 40D may include jog patterns 44a and 44b. The jog pattern 44a may connect the third pattern 11c of the first standard cell SC1 to the third pattern 12c of the second standard cell SC2, and the jog pattern 44b may connect the fourth pattern 11d of the first standard cell SC1 to the fourth pattern 12d of the second standard cell SC2. As described above, each of the filler cells 40C and 40D may include two jog patterns. In this case, patterns connected to both sides of each of the two jog patterns may vary with embodiments.

Referring to FIGS. 1, 4E, and 4F, a filler cell 40E may include jog patterns 45a, 45b, and 45c. The jog pattern 45a may connect the first pattern 11a of the first standard cell SC1 to the first pattern 12a of the second standard cell SC2, the jog pattern 45b may connect the second pattern 11b of the first standard cell SC1 to the second pattern 12b of the second standard cell SC2, and the jog pattern 45c may connect the third pattern 11c of the first standard cell SC1 to the third pattern 12c of the second standard cell SC2. The filler cell 40F may include jog patterns 46a, 46b, and 46c. The jog pattern 46a may connect the second pattern 11b of the first standard cell SC1 to the second pattern 12b of the second standard cell SC2, the jog pattern 46b may connect the third pattern 11c of the first standard cell SC1 to the third pattern 12c of the second standard cell SC2, and the jog pattern 46c may connect the fourth pattern 11d of the first standard cell SC1 to the fourth pattern 12d of the second standard cell SC2. As described above, each of the filler cells 40E and 40F may include three jog patterns. In this case, patterns connected to both sides of each of three jog patterns may vary with embodiments.

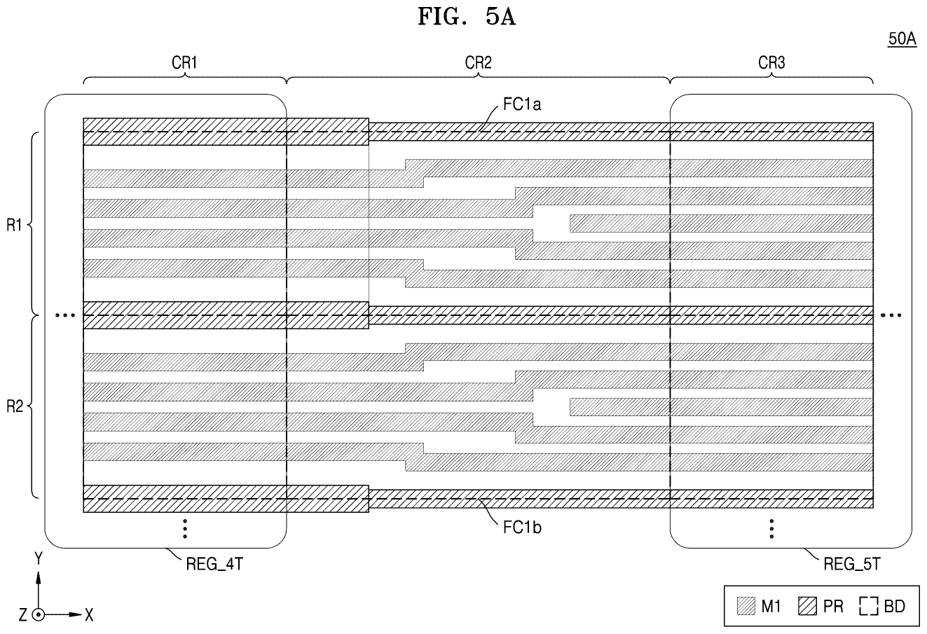

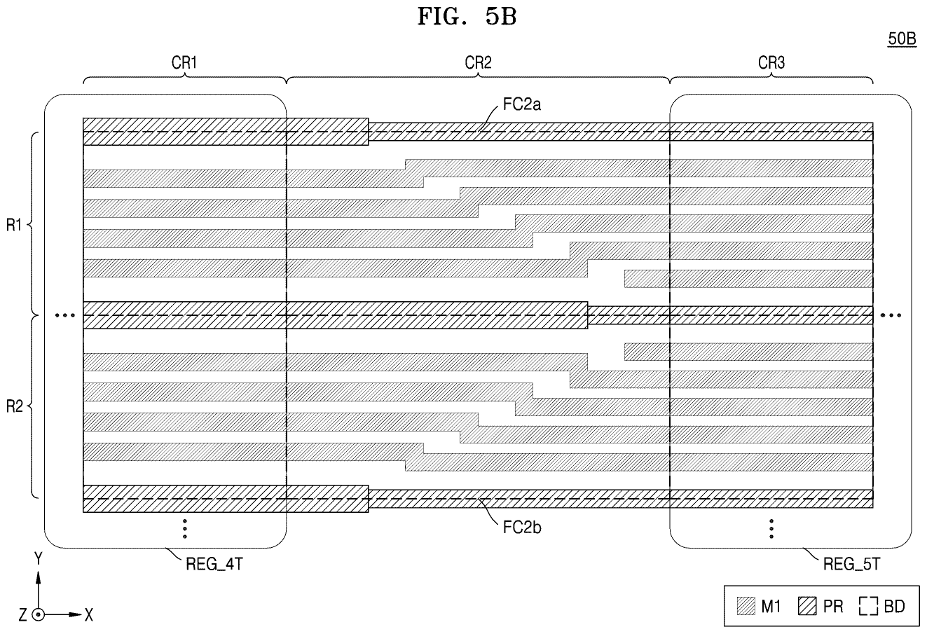

FIG. 5A illustrates an IC 50A according to one or more embodiments.

Referring to FIG. 5A, the IC 50A may include first to third columns CR1, CR2, and CR3 arranged in the first direction X. The first column CR1 may be spaced apart from the third column CR3 in the first direction X. The first column CR1 may include first standard cells, which are arranged in the second direction Y, and each first standard cell may have an N-track structure, and therefore, may be referred to as a first standard cell group. The third column CR3 may include second standard cells, which are arranged in the second direction Y, and each second standard cell may have an M-track structure, and therefore, may be referred to as a second standard cell group. In one or more examples, N and M may be different positive integers.

In one or more embodiments, the first column CR1 may include a 4-track region REG_4T having a 4-metal track structure. The first column CR1 may include first standard cells respectively arranged in first and second rows R1 and R2. Four metal tracks may be routed above each first standard cell. For example, the third column CR3 may include a 5-track region REG_5T having a 5-metal track structure. The third column CR3 may include second standard cells respectively arranged in the first and second rows R1 and R2. Five metal tracks may be routed above each second standard cell.

The second column CR2 may be arranged between the first and third columns CR1 and CR3 and may include a plurality of filler cells arranged in the second direction Y. For example, the second column CR2 may include a first filler cell FC1a in the first row R1 and a second filler cell FC1b in the second row R2. The first and second filler cells FC1a and FC1b may have the same shape and each may include at least one jog pattern. For example, each of the first and second filler cells FC1a and FC1b may be implemented like the filler cell 30A of FIG. 3A, but the embodiments of the present disclosure are not limited thereto.

The IC 50A may further include power rails PR, which respectively overlap cell boundaries BD of the first and second standard cells and extend in the first direction X. Power rails above the first column CR1 and power rails above the third column CR3 may have different widths in the second direction Y. Metal tracks and jog patterns may be at the same level as the power rails PR. Accordingly, the power rails PR may be adaptively routed to the metal tracks and the jog patterns. The various embodiments of filler cells described with reference to FIGS. 1 to 4F may be applied to the present embodiment.

FIG. 5B illustrates an IC 50B according to one or more embodiments.

Referring to FIG. 5B, the IC 50B may be correspond to a modification of the IC 50A of FIG. 5A. The second column CR2 may be arranged between the first and third columns CR1 and CR3 and may include a plurality of filler cells arranged in the second direction Y. For example, the second column CR2 may include a first filler cell FC2a in the first row R1 and a second filler cell FC2b in the second row R2. The first and second filler cells FC2a and FC2b may be symmetrical with each other in the second direction Y. For example, the first filler cell FC2a may be implemented in accordance with the filler cell 30E of FIG. 3E, and the second filler cell FC2b may be implemented in accordance with the filler cell 30F of FIG. 3F, but the embodiments of the present disclosure are not limited thereto.

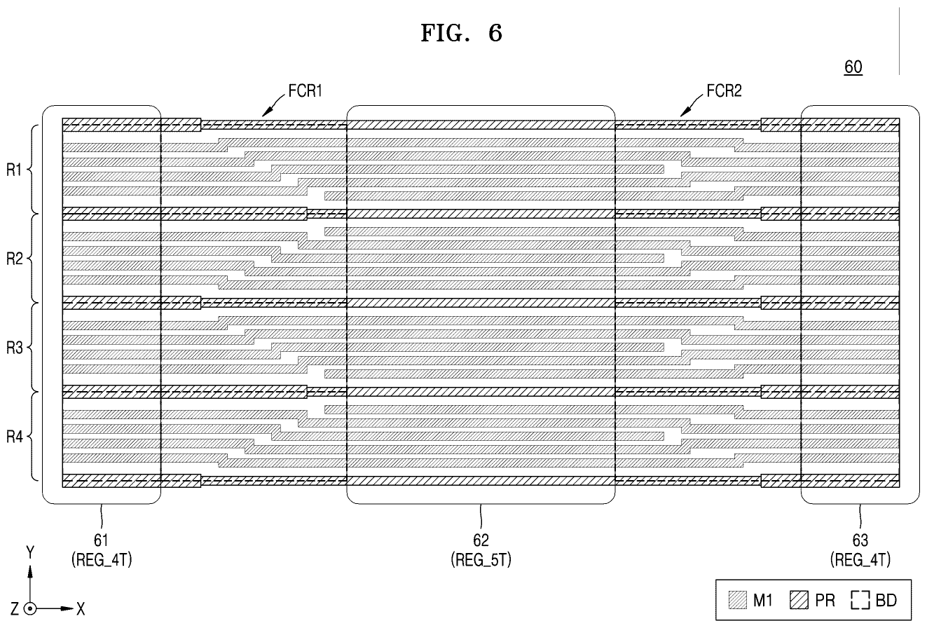

FIG. 6 illustrates an IC 60 according to one or more embodiments.

Referring to FIG. 6, the IC 60 may include first to third regions 61, 62, and 63. For example, the first and third regions 61 and 63 may respectively correspond to 4-track regions REG_4T, and the second region 62 may correspond to a 5-track region REG_5T. In this case, the first region 61 may include first standard cells arranged in the second direction Y. Four metal tracks may be routed above each first standard cell. The second region 62 may include second standard cells arranged in the second direction Y. Five metal tracks may be routed above each second standard cell. The third region 63 may include third standard cells arranged in the second direction Y. Four metal tracks may be routed above each third standard cell.

A first filler cell column FCR1 may be arranged between the first and second regions 61 and 62, and may include a plurality of filler cells arranged in the second direction Y. For example, the first filler cell column FCR1 may include filler cells respectively arranged in first to fourth rows R1 to R4. In this case, the filler cells respectively arranged in the first and third rows R1 and R3 may be implemented in the same manner, for example, in accordance with the filler cell 30E of FIG. 3E. The filler cells respectively arranged in the second and fourth rows R2 and R4 may be implemented in the same manner, for example, in accordance with the filler cell 30F of FIG. 3F.

A second filler cell column FCR2 may be arranged between the second and third regions 62 and 63, and may include a plurality of filler cells arranged in the second direction Y. For example, the second filler cell column FCR2 may include filler cells respectively arranged in the first to fourth rows R1 to R4. In one or more examples, the filler cells respectively arranged in the first to fourth rows R1 to R4 may be implemented in the same manner and each may have, for example, a form with which the filler cell 30A of FIG. 3A is symmetrical with respect to the Y axis.

The IC 60 may further include power rails PR, which respectively overlap cell boundaries BD of the first to third standard cells and extend in the first direction X. Power rails above the first and third standard cells and power rails above the second standard cells may have different widths in the second direction Y. Metal tracks and jog patterns may be at the same level as the power rails PR. Accordingly, the power rails PR may be adaptively routed to the metal tracks and the jog patterns. The various embodiments of filler cells described with reference to FIGS. 1 to 4F may be applied to the present embodiment.

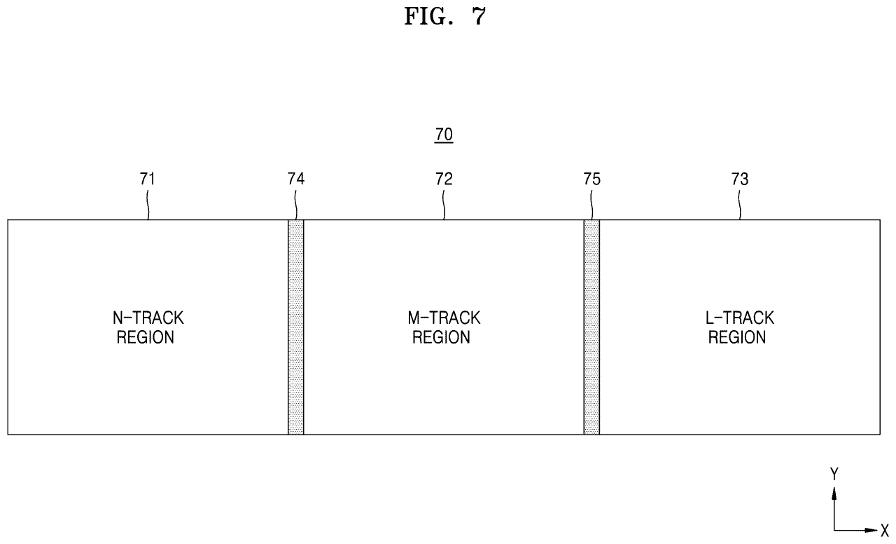

FIG. 7 illustrates an IC 70 according to one or more embodiments.

Referring to FIG. 7, the IC 70 may include first to third regions 71, 72, and 73. For example, the first region 71 may correspond to an N-track region, the second region 72 may correspond to an M-track region, and the third region 73 may correspond to an L-track region. In one or more embodiments, N, M, and L may be different positive integers. However, the embodiments of the present disclosure are not limited thereto. In some embodiments, N and L may be the same positive integer, and M may be a positive integer different from N and L.

In the first region 71, a plurality of first standard cells may be arranged in accordance with an N-track structure. N metal tracks may be routed above each first standard cell. In the second region 72, a plurality of second standard cells may be arranged in accordance with an M-track structure. M metal tracks may be routed above each second standard cell. In the third region 73, a plurality of third standard cells may be arranged in accordance with an L-track structure. L metal tracks may be routed above each third standard cell.

The IC 70 may further include a fourth region 74 between the first and second regions 71 and 72 and a fifth region 75 between the second and third regions 72 and 73. In the fourth region 74, a plurality of first filler cells may be arranged in the second direction Y. Each of the first filler cells may include at least one jog pattern connecting one of N metal tracks above a first standard cell to one of M metal tracks above a second standard cell. In the fifth region 75, a plurality of second filler cells may be arranged in the second direction Y. Each of the second filler cells may include at least one jog pattern connecting one of M metal tracks above a second standard cell to one of L metal tracks above a third standard cell.

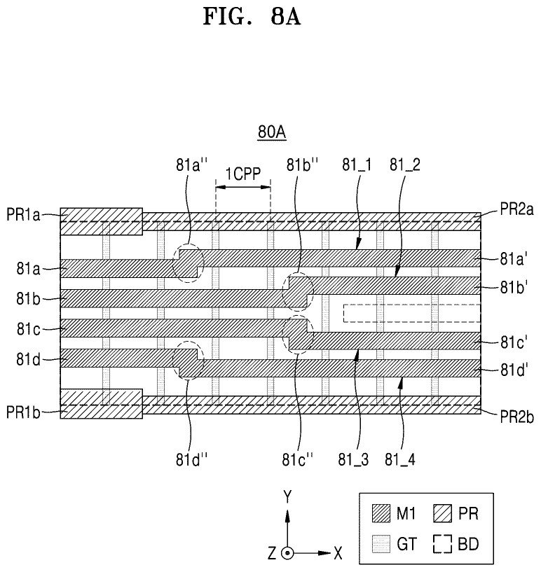

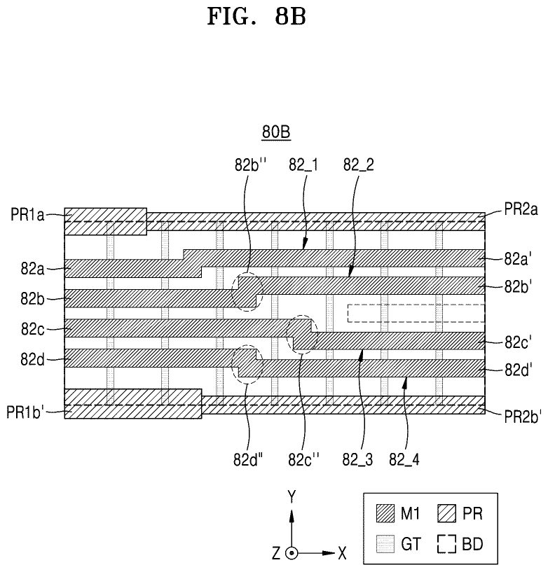

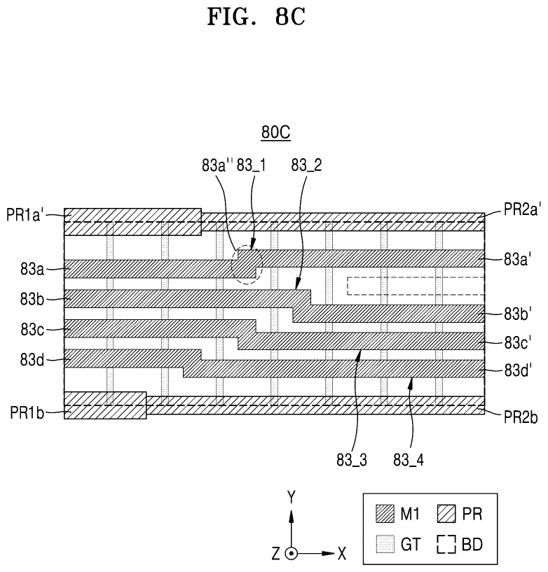

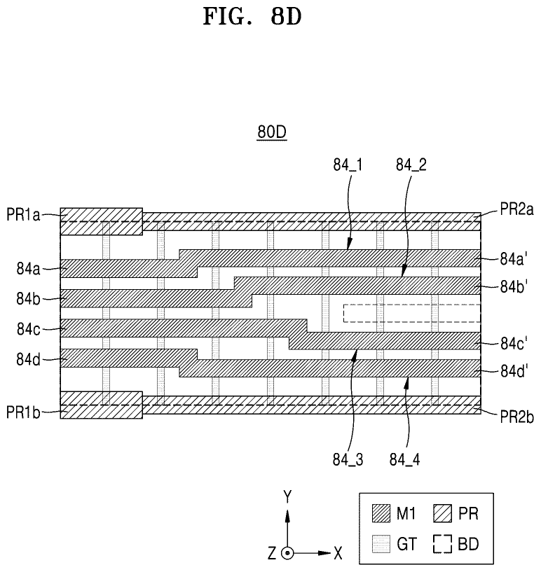

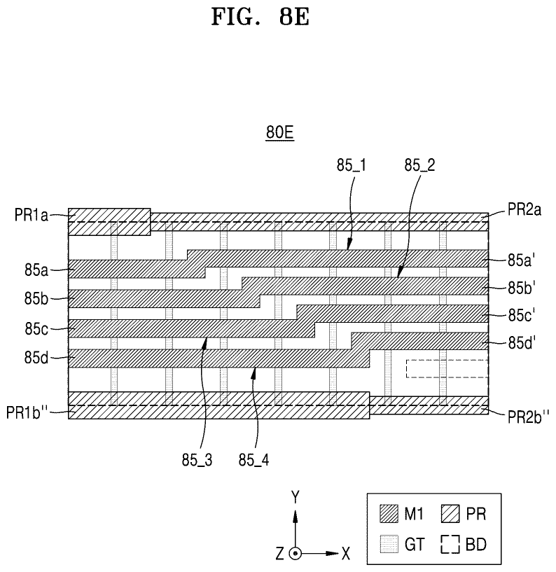

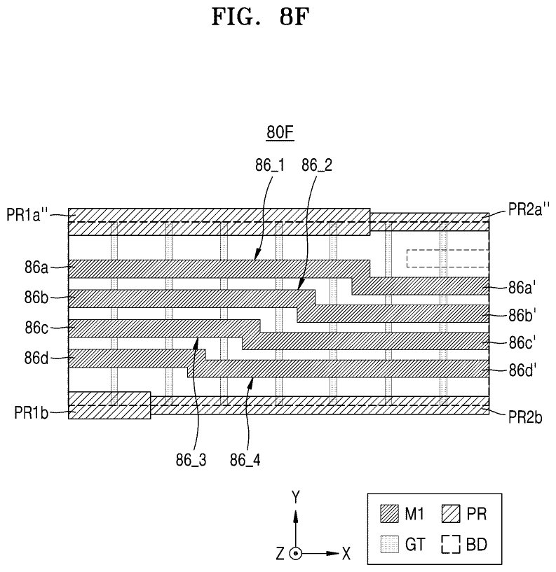

FIG. 8A illustrates a filler cell 80A according to one or more embodiments.

Referring to FIG. 8A, the filler cell 80A may include a plurality of gate lines GT, power rails PR, and jog patterns 81_1 to 81_4. For example, the jog patterns 81_1 to 81_4 may be included in the first metal layer M1. In some embodiments, the power rails PR may be included in the first metal layer M1. The gate lines GT may extend in the second direction Y and may be spaced apart from each other in the first direction X. The gate lines GT of the filler cell 80A may be used as dummy gate lines.

The power rails PR may include first and second power rails PR1a and PR2a, which have different widths, and first and second power rails PR1b and PR2b, which have different widths. The jog patterns 81_1 to 814 may be arranged to have at least a minimum distance from the first and second power rails PR1a, PR1b, PR2a, and PR2b. For example, the first and second power rails PR1a, PR1b, PR2a, and PR2b may be adaptively routed to adjacent jog patterns. The power rails PR and the jog patterns 81_1 to 81_4 may be arranged above the gate lines GT in the vertical direction Z, but the embodiments of the present disclosure are not limited thereto.

The jog pattern 81_1 may include a first portion 81a and a second portion 81a′. A region in which the first portion 81a is in contact with the second portion 81a′ may be referred to as a junction region 81a″. The jog pattern 81_2 may include a first portion 81b and a second portion 81b′. A region in which the first portion 81b is in contact with the second portion 81b′ may be referred to as a junction region 81b″. The jog patterns 81_1 and 81_2 may have an upwardly bent shape.

The jog pattern 81_3 may include a first portion 81c and a second portion 81c′. A region in which the first portion 81c is in contact with the second portion 81c′ may be referred to as a junction region 81c″. The jog pattern 81_4 may include a first portion 81d and a second portion 81d′. A region in which the first portion 81d is in contact with the second portion 81d′ may be referred to as a junction region 81d″. The jog patterns 81_3 and 81_4 may have a downwardly bent shape.

In one or more embodiments, each of the junction regions 81a″ to 81d″ may be between gate lines GT. In other words, the junction regions 81a″ to 81d″ may not overlap the gate lines GT. In one or more embodiments, the spacing between the junction region 81a″ and the junction region 81b″ may be at least 1 contacted poly pitch (CPP), and the spacing between the junction region 81c″ and the junction region 81d″ may also be at least 1 CPP. In this case, CPP may correspond to the spacing between the gate lines GT. In one or more embodiments, the junction region 81b″ and the junction region 81c″ may be adjacent to each other in the second direction Y. For example, the junction region 81b″ and the junction region 81c″ may be aligned with each other. In one or more embodiments, the junction regions 81a″ to 81d″ may have substantially the same height in the second direction Y, but the embodiments of the present disclosure are not limited thereto.

FIG. 8B illustrates a filler cell 80B according to one or more embodiments.

Referring to FIG. 8B, the filler cell 80B corresponds to a modification of the filler cell 80A of FIG. 8A, and thus redundant descriptions thereof are omitted. The filler cell 80B may include jog patterns 82_1 to 82_4. The jog pattern 82_1 may include a first portion 82a and a second portion 82a′. The jog pattern 82_2 may include a first portion 82b and a second portion 82b′. The jog pattern 82_3 may include a first portion 82c and a second portion 82c′. In one or more embodiments, a junction region 82b″ and a junction region 82c″ may not be adjacent to each other in the second direction Y. In other words, the junction region 82b″ and the junction region 82c″ may not be aligned with each other.

The jog pattern 82_4 may include a first portion 82d and a second portion 82d′. For example, the length of the first portion 82d may be greater than the length of the first portion 81d in FIG. 8A, and the length of the second portion 82d′ may be less than the length of the second portion 81d′ in FIG. 8A Accordingly, the position of a junction region 82d″ may be different from the position of the junction region 81d″ in FIG. 8A. First and second power rails PR1b′ and PR2b′ may be adaptively routed to the jog pattern 82_4. For example, the length of the first power rail PR1b′ in the first direction X may be greater than the length of the first power rail PR1b in the first direction X in FIG. 8A.

FIG. 8C illustrates a filler cell 80C according to one or more embodiments.

Referring to FIG. 8C, the filler cell 80C corresponds to a modification of the filler cell 80A of FIG. 8A, and thus redundant descriptions thereof are omitted. The filler cell 80C may include jog patterns 83_1 to 83_4. The jog pattern 83_1 may include a first portion 83a and a second portion 83a′. The jog pattern 83_2 may include a first portion 83b and a second portion 83b′. The jog pattern 83_3 may include a first portion 83c and a second portion 83c′. The jog pattern 83_4 may include a first portion 83d and a second portion 83d′. The jog pattern 83_1 may have an upwardly bent shape and the jog patterns 83_2 to 83_4 may have a downwardly bent shape.

In one or more examples, the length of the first portion 83a may be greater than the length of the first portion 81a in FIG. 8A, and the length of the second portion 83a′ may be less than the length of the second portion 81a′ in FIG. 8A Accordingly, the position of a junction region 83a″ may be different from the position of the junction region 81a″ in FIG. 8A. First and second power rails PR1a′ and PR2a′ may be adaptively routed to the jog pattern 83_1. For example, the length of the first power rail PR1a′ in the first direction X may be greater than the length of the first power rail PR1a in the first direction X in FIG. 8A.

FIG. 8D illustrates a filler cell 80D according to one or more embodiments.

Referring to FIG. 8D, the filler cell 80D corresponds to a modification of the filler cell 80A of FIG. 8A, and thus redundant descriptions thereof are omitted. The filler cell 80D may include jog patterns 84_1 to 84_4. The jog pattern 84_1 may include a first portion 84a and a second portion 84a′. The jog pattern 84_2 may include a first portion 84b and a second portion 84b′. The jog patterns 84_1 and 84_2 may have a downwardly bent shape. The jog pattern 84_3 may include a first portion 84c and a second portion 84c′. The jog pattern 84_4 may include a first portion 84d and a second portion 84d′. The jog patterns 84_3 and 844 may have an upwardly bent shape.

FIG. 8E illustrates a filler cell 80E according to one or more embodiments.

Referring to FIGS. 1 and 8E, the filler cell 80E corresponds to a modification of the filler cell 80A of FIG. 8A, and thus redundant descriptions thereof are omitted. The filler cell 80E may include jog patterns 85_1 to 85_4. The jog pattern 85_1 may include a first portion 85a and a second portion 85a′. The jog pattern 85_2 may include a first portion 85b and a second portion 85b′. The jog pattern 85_3 may include a first portion 85c and a second portion 85c′.

The jog pattern 85_4 may include a first portion 85d and a second portion 85d′. For example, the length of the first portion 85d may be greater than the length of the first portion 81d in FIG. 8A, and the length of the second portion 85d′ may be less than the length of the second portion 81d′ in FIG. 8A First and second power rails PR1b″ and PR2b″ may be adaptively routed to the jog pattern 85_4. For example, the length of the first power rail PR1b″ in the first direction X may be greater than the length of the first power rail PR1b in the first direction X in FIG. 8A. The jog patterns 85_1 to 85_4 may have an upwardly bent shape.

FIG. 8F illustrates a filler cell 80F according to one or more embodiments.

Referring to FIG. 8F, the filler cell 80F corresponds to a modification of the filler cell 80A of FIG. 8A, and thus redundant descriptions thereof are omitted. The filler cell 80F may include jog patterns 86_1 to 86_4. The jog pattern 86_1 may include a first portion 86a and a second portion 86a′. For example, the length of the first portion 86a may be greater than the length of the first portion 81a in FIG. 8A, and the length of the second portion 86a′ may be less than the length of the second portion 81a′ in FIG. 8A First and second power rails PR1a″ and PR2a″ may be adaptively routed to the jog pattern 86_1. For example, the length of the first power rail PR1a″ in the first direction X may be greater than the length of the first power rail PR1a in the first direction X in FIG. 8A.

The jog pattern 86_2 may include a first portion 86b and a second portion 86b′. The jog pattern 86_3 may include a first portion 86c and a second portion 86c′. The jog pattern 86_4 may include a first portion 86d and a second portion 86d′. The jog patterns 86_1 to 864 may have a downwardly bent shape.

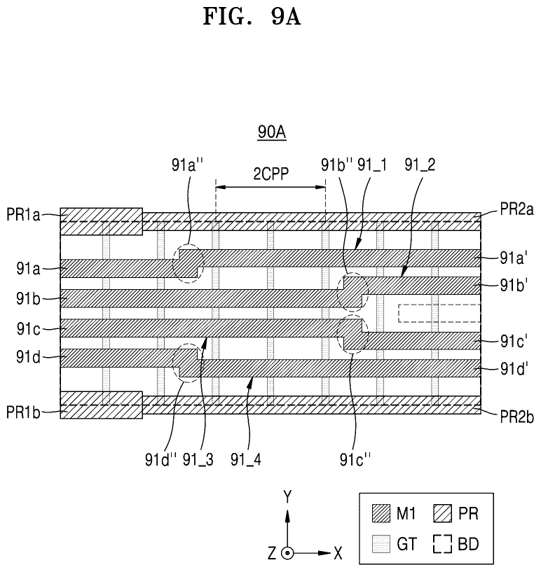

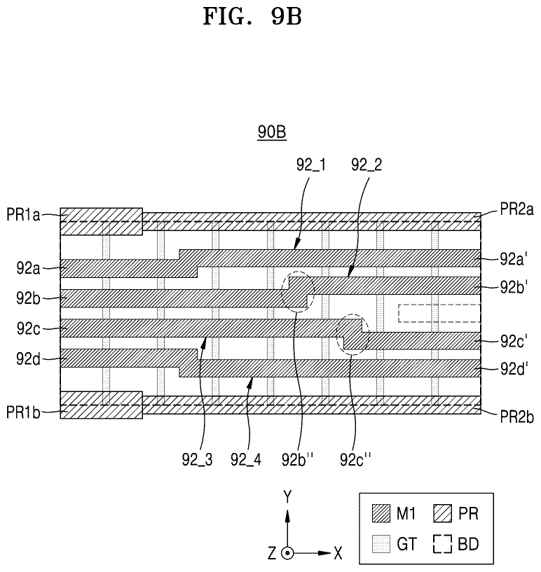

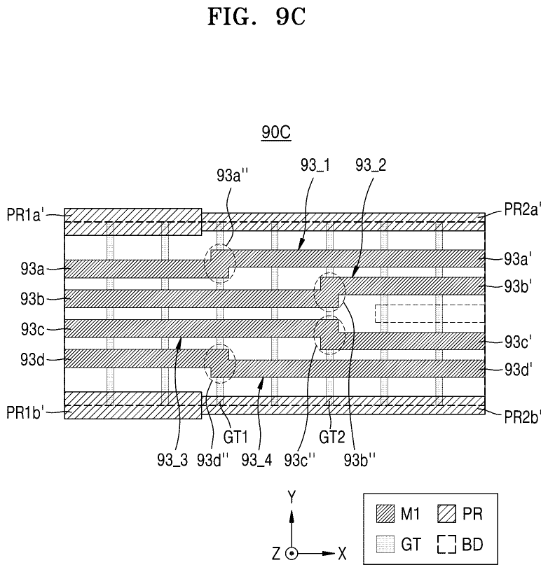

FIG. 9A illustrates a filler cell 90A according to one or more embodiments.

Referring to FIG. 9A, the filler cell 90A corresponds to a modification of the filler cell 80A of FIG. 8A. The filler cell 90A may include jog patterns 91_1 to 91_4. The jog pattern 91_1 may include a first portion 91a and a second portion 91a′. The jog pattern 91_2 may include a first portion 91b and a second portion 91b′. The jog pattern 913 may include a first portion 91c and a second portion 91c′. The jog pattern 91_4 may include a first portion 91d and a second portion 91d′.

In one or more embodiments, the spacing between a junction region 91a″ and a junction region 91b″ may be at least 2 CPP, and the spacing between a junction region 91c″ and a junction region 91d″ may also be at least 2 CPP. In this case, CPP may correspond to the spacing between the gate lines GT. In one or more embodiments, the junction region 91b″ and the junction region 91c″ may be adjacent to each other in the second direction Y. For example, the junction region 91b″ and the junction region 91c″ may be aligned with each other.

FIG. 9B illustrates a filler cell 90B according to one or more embodiments.

Referring to FIG. 9B, the filler cell 90B corresponds to a modification of the filler cell 80A of FIG. 8A. The filler cell 90B may include jog patterns 92_1 to 92_4. The jog pattern 92_1 may include a first portion 92a and a second portion 92a′. The jog pattern 92_2 may include a first portion 92b and a second portion 92b′. The jog pattern 923 may include a first portion 92c and a second portion 92c′. The jog pattern 92_4 may include a first portion 92d and a second portion 92d′. In one or more embodiments, a junction region 92b″ and a junction region 92c″ may not be adjacent to each other in the second direction Y. For example, the junction region 92b″ and the junction region 92c″ may not be aligned with each other.

FIG. 9C illustrates a filler cell 90C according to one or more embodiments.

Referring to FIG. 9C, the filler cell 90C corresponds to a modification of the filler cell 80A of FIG. 8A. The filler cell 90C may include jog patterns 93_1 to 93_4. The jog pattern 93_1 may include a first portion 93a and a second portion 93a′. The jog pattern 93_2 may include a first portion 93b and a second portion 93b′. The jog pattern 933 may include a first portion 93c and a second portion 93c′. The jog pattern 93_4 may include a first portion 93d and a second portion 93d′. In one or more embodiments, junction regions 93a″ to 93d″ each may overlap a gate line GT. For example, the junction regions 93a″ and 93d″ may overlap a first gate line GT1, and the junction regions 93b″ and 93c″ may overlap a second gate line GT2.

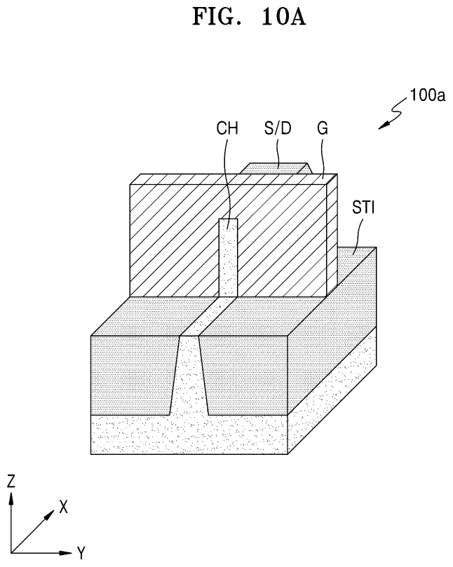

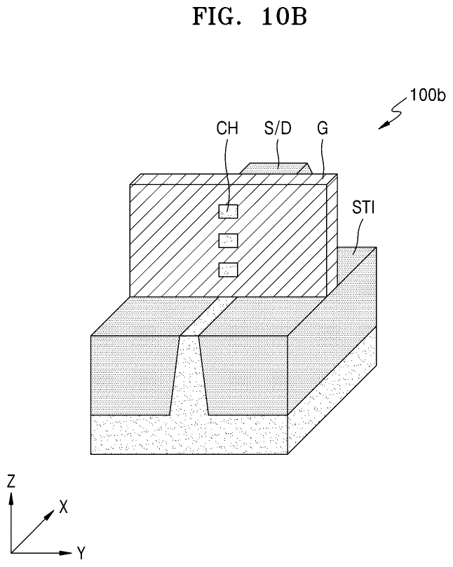

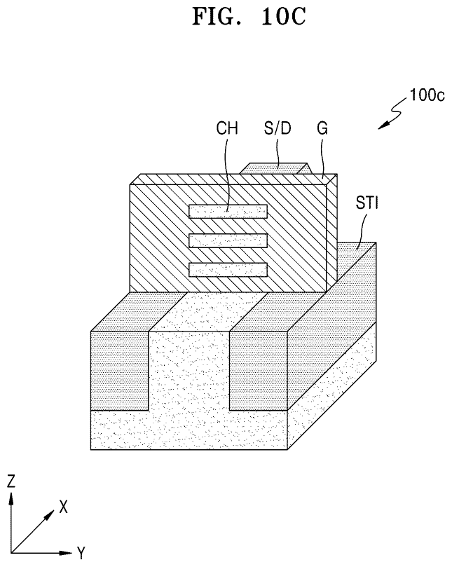

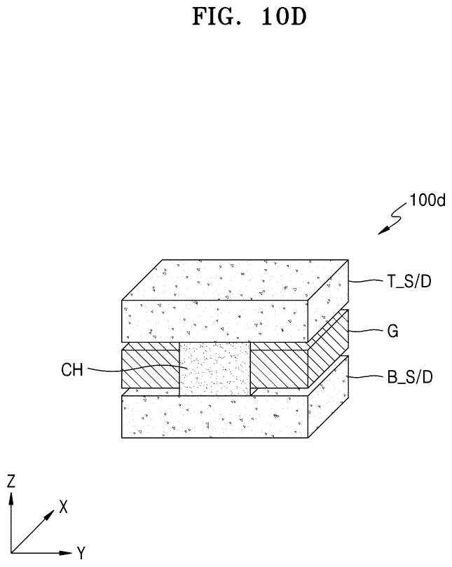

FIGS. 10A to 10D illustrate devices according to some embodiments. For example, FIG. 10A illustrates a fin field effect transistor (FinFET) 100a. FIG. 10B illustrates a gate-all-around FET (GAAFET) 100b. FIG. 10C illustrates multi-bridge channel FET (MBCFET) 100c. FIG. 10D illustrates a vertical FET (VFET) 100d. For convenience of illustration, one of two source/drain regions is omitted from FIGS. 10A to 10C, and FIG. 10D illustrates a cross-section of the VFET 100d taken along a plane, which is parallel with a plane formed by the second direction Y and the vertical direction Z and passes through a channel CH of the VFET 100d.

Referring to FIG. 10A, the FinFET 100a may include a fin-shaped active pattern extending in the first direction X between shallow trench isolations (STIs) and a gate G extending in the second direction Y. A source/drain S/D may be at each of opposite sides of the gate G, and thus, a source and a drain may be separated from each other in the first direction X. An insulating film may be between a channel CH and the gate G. In some embodiments, the FinFET 100a may include the gate G and a plurality of active patterns separated from each other in the second direction Y.

Referring to FIG. 10B, the GAAFET 100b may include active patterns (e.g., nanowires) which are separated from each other in the vertical direction Z and extend in the first direction X, and a gate G extending in the second direction Y. A source/drain S/D may be at each of opposite sides of the gate G, and thus, a source and a drain may be separated from each other in the first direction X. An insulating film may be between a channel CH and the gate G. The number of nanowires in the GAAFET 100b is not limited to that illustrated in FIG. 10B.

Referring to FIG. 10C, the MBCFET 100c may include active patterns (e.g., nanosheets), which are separated from each other in the vertical direction Z and extend in the first direction X, and a gate G extending in the second direction Y. A source/drain S/D may be at each of opposite sides of the gate G, and thus, a source and a drain may be separated from each other in the first direction X. An insulating film may be between a channel CH and the gate G. The number of nanosheets in the MBCFET 100c is not limited to that illustrated in FIG. 10C.

Referring to FIG. 10D, the VFET 100d may include a top source/drain T_S/D and a bottom source/drain B_S/D, which are separated from each other by a channel CH in the vertical direction Z. The VFET 100d may further include a gate G, which is between the top source/drain T_S/D and the bottom source/drain B_S/D and surrounds the channel CH. An insulating film may be between a channel CH and the gate G.

According to the present embodiment, an IC may include a plurality of standard cells, and each standard cell may include various transistors illustrated in FIGS. 10A to 10D. However, a transistor according to embodiments is not limited to those structures described above. For example, an IC may include a ForkFET having a structure in which an n-type transistor and a p-type transistor are close to each other because nanosheets for the p-type transistor and nanosheets for the n-type transistor are separated from each other by a dielectric wall. An IC may include a bipolar junction transistor as well as an FET such as a complementary FET (CFET), a negative CFET (NCFET), or a carbon nanotube (CNT) FET.

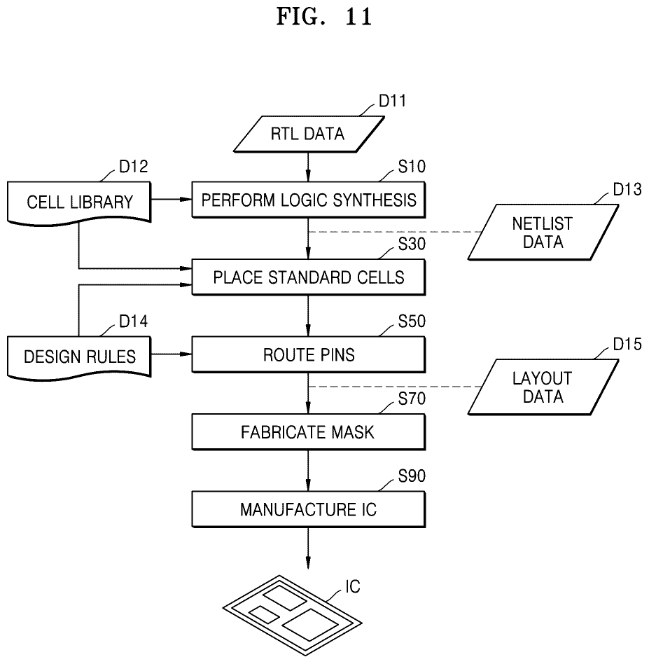

FIG. 11 is a flowchart of a method of manufacturing an IC, according to one or more embodiments.

Referring to FIG. 11, the method of the present embodiment is a method of manufacturing an IC including standard cells and may include operations S10, S30, S50, S70, and S90. A cell library (or a standard cell library) D12 may include information about standard cells (e.g., information about functions, characteristics, layouts, or the like of standard cells). In some embodiments, the cell library D12 may define a tap cell, a filler cell, and a dummy cell as well as function cells generating output signals from input signals. For example, the cell library D12 may define filler cells between standard cells having different metal track structures. Design rules D14 may include requirements for the layout of an IC. For example, the design rules D14 may include requirements for the spacing between patterns in one layout, the minimum width of a pattern, the routing direction of a wiring layer, and the like. In some embodiments, the design rules D14 may define the minimum spacing in a track of a wiring layer.

Logic synthesis, by which netlist data D13 is generated from RTL data D11, may be performed in operation S10. For example, a semiconductor design tool (e.g., a logic synthesis tool) may perform logic synthesis on the RTL data D11, which is written in very high speed IC (VHSIC) hardware description language (HDL) (VHDL) and HDL such as Verilog, with reference to the cell library D12 and may generate the netlist data D13 including a bitstream or a netlist. The netlist data D13 may correspond to the placement and routing input, which is described below.

Standard cells may be placed in operation S30. For example, a semiconductor design tool (e.g., a P&R tool) may place standard cells, which are used in the netlist data D13, with reference to the cell library D12. In some embodiments, the semiconductor design tool may place a standard cell in a lane extending in the X-axis direction or the Y-axis direction. The placed standard cell may be supplied with power from a power rail extending along a boundary of the lane.

The pins of the standard cells may be routed in operation S50. For example, a semiconductor design tool may generate interconnections that electrically connect the output and input pins of placed standard cells and generate layout data D15 that defines the placed standard cells and the interconnections. An interconnection may include a via of a via layer and/or patterns of wiring layers. The wiring layers may include a front wiring layer disposed on the front surface of a substrate and a back wiring layer disposed on the back surface of the substrate. For example, the layout data D15 may have a format like GDSII and include geometrical information of cells and interconnections. A semiconductor design tool may refer to the design rules D14 while routing the pins of cells. The layout data D15 may correspond to the output of placement and routing. Operation S50 alone or operations S30 and S50 may be collectively referred to as a method of designing an IC.

In one or more embodiments, as illustrated in FIGS. 1 to 9C, an IC may include first and second standard cells having different metal track structures and a filler cell between the first standard cell and the second standard cell. The filler cell may include jog patterns connecting metal tracks, which are arranged above the first standard cell according to a first metal track structure, to metal tracks, which are arranged above the second standard cell according to a second metal track structure, and may transfer signals through the jog patterns. Accordingly, the performance of the IC may be increased, and wiring and routing freedom may also be increased because standard cells are placed according to various architectures in the same block.

A mask may be fabricated in operation S70. For example, optical proximity correction (OPC) for correcting distortion, such as refraction, caused by the characteristics of light in photolithography may be performed on the layout data D15. Patterns on a mask may be defined to form patterns arranged in a plurality of layers, based on data that has undergone OPC, and at least one mask (or photomask) for forming patterns of each layer may be manufactured. In some embodiments, the layout of an IC may be limitedly modified in operation S70. Limitedly modifying an IC in operation S70 may be post processing for optimizing the structure of the IC and referred to as design polishing.

An IC may be manufactured in operation S90. For example, an IC may be manufactured by patterning a plurality of layers by using at least one mask, which is fabricated in operation S70. For example, FEOL may include planarizing and cleaning a wafer, forming a trench, forming a well, forming a gate line, and forming a source and a drain. Individual devices (e.g., transistors, capacitors, resistors, etc.) may be formed in a substrate via the FEOL. Back-end-of-line (BEOL) may include silicidation of a gate and source and drain regions, adding a dielectric, planarization, forming a hole, adding a metal layer, forming a via, and forming a passivation layer. The individual devices (e.g., transistors, capacitors, resistors, etc.) may be interconnected with each other via the BEOL. In some embodiments, middle-of-line (MOL) may be performed between FEOL and BEOL such that contacts may be formed on individual devices. Thereafter, the IC may be packaged in a semiconductor package and used as a component of various applications.

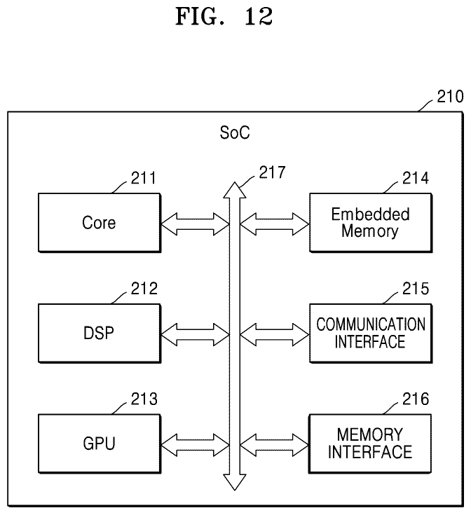

FIG. 12 is a block diagram of a system-on-chip (SoC) 210 according to one or more embodiments.

Referring to FIG. 12, the SoC 210 may refer to an IC in which components of a computing system or another electronic system are integrated. For example, an application processor (AP) as an example of the SoC 210 may include a processor and components for other functions. The SoC 210 may include a core 211, a digital signal processor (DSP) 212, a graphics processing unit (GPU) 213, an embedded memory 214, a communication interface 215, and a memory interface 216. The elements of the SoC 210 may communicate with one another through a bus 217.

The core 211 may process instructions and control the operations of the elements of the SoC 210. For example, the core 211 may drive an operating system (OS) by processing a series of instructions and execute applications on the OS. The DSP 212 may generate useful data by processing a digital signal, for example, provided from the communication interface 215. The GPU 213 may generate data, which corresponds to an image output on a display device, from image data provided from the embedded memory 214 or the memory interface 216 or may encode the image data. In some embodiments, the IC described above with reference to the drawings may be included in the core 211, the DSP 212, the GPU 213, and/or the embedded memory 214.

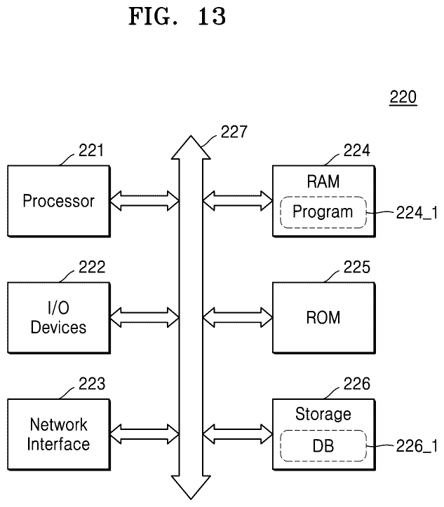

FIG. 13 is a block diagram of a computing system 220 including memory storing a program, according to one or more embodiments.

Referring to FIG. 13, a method of designing an IC (e.g., at least some of the operations in the flowchart described above), according to embodiments may be performed by the computing system (or a computer) 220. The computing system 220 may include a processor 221, input/output (I/O) devices 222, a network interface 223, random-access memory (RAM) 224, read-only memory (ROM) 225, and a storage 226. The processor 221, the I/O devices 222, the network interface 223, the RAM 224, the ROM 225, and the storage 226 may be connected to a bus 227 and communicate with one another through the bus 227.

The processor 221 may access memory (e.g., the RAM 224 or the ROM 225) through the bus 227 and execute instructions stored in the RAM 224 or the ROM 225. The RAM 224 may store a program 224_1 for executing a method of designing an IC, according to one or more embodiments, or at least part of the program 2241. The program 2241 may enable the processor 221 to perform at least some of the operations included in the method of designing an IC (e.g., the method of FIG. 11. In other words, the program 2241 may include a plurality of instructions executable by the processor 221, and the instructions included in the program 2241 may enable the processor 221 to perform at least some of the operations included in the flowchart described above.

The storage 226 may store the program 224_1, according to one or more embodiments. The storage 226 may store a database (DB) 2261. The DB 226_1 may include information necessary to design an IC (e.g., information about designed blocks, the cell library D12 in FIG. 11, and/or the design rules D14 in FIG. 11. The storage 226 may store data to be processed by the processor 221 or data that has been processed by the processor 221. For example, the storage 226 may store the RTL data D11, the netlist data D13, and/or the layout data D15 in FIG. 11.

While the embodiments has been particularly shown and described with reference to embodiments thereof, it will be understood that various changes in form and details may be made therein without departing from the spirit and scope of the following claims.

What is claimed is:

1. An integrated circuit comprising:
a first standard cell comprising a first set of a plurality of patterns extending in a first direction, the first standard cell having a first pitch;
a second standard cell comprising a second set of a plurality of patterns extending in the first direction, the second standard cell having a second pitch different from the first pitch, the second standard cell spaced apart from the first standard cell in the first direction;
a signal transfer filler cell between the first standard cell and the second standard cell, the signal transfer filler cell comprising at least one jog pattern connecting one pattern in the first set of the plurality of patterns to one pattern in the second set of the plurality of patterns;
a first power rail having a first width in a second direction perpendicular to the first direction above the first standard cell; and
a second power rail having a second width different from the first width in the second direction above the second standard cell.

2. The integrated circuit of claim 1, wherein a number of the first set of the plurality of patterns is different from a number of the second set of the plurality of patterns.

3. The integrated circuit of claim 1, wherein:
the first set of the plurality of patterns comprises a first pattern and a second pattern,
the second set of the plurality of patterns comprises a third pattern and a fourth pattern, and
the at least one jog pattern comprises:
a first jog pattern connecting the first pattern to the third pattern, and
a second jog pattern connecting the second pattern to the fourth pattern.

4. The integrated circuit of claim 3, wherein the first jog pattern and the second jog pattern have a same pattern shape.

5. The integrated circuit of claim 3, wherein:
the first jog pattern comprises a first portion in contact with the first pattern and a second portion in contact with the third pattern,
the second portion is not aligned with the first portion,
the second jog pattern comprises a third portion in contact with the second pattern and a fourth portion in contact with the fourth pattern, and
the fourth portion is not aligned with the third portion.

6. The integrated circuit of claim 5, wherein:
the first portion and the third portion have different lengths in the first direction, and
the second portion and the fourth portion have different lengths in the first direction.

7. The integrated circuit of claim 5, wherein a first spacing between the first portion and the third portion is different from a second spacing between the second portion and the fourth portion.

8. The integrated circuit of claim 1, wherein the first power rail and the second power rail each extend in the first direction.

9. The integrated circuit of claim 1, wherein the first set of the plurality of patterns, the second set of the plurality of patterns, and the at least one jog pattern are arranged in a same layer.

10. The integrated circuit of claim 1, wherein the first power rail, the second power rail, the first set of the plurality of patterns, the second set of the plurality of patterns, and the at least one jog pattern are arranged in a same layer.

11. An integrated circuit comprising:
a first standard cell comprising an N-track structure;
a second standard cell comprising an M-track structure, the second standard cell spaced apart from the first standard cell in a first direction;
a signal transfer filler cell between the first standard cell and the second standard cell;
a first power rail connected to the first standard cell, the first power rail having a first width in a second direction perpendicular to the first direction;
a second power rail connected to the second standard cell, the second power rail having a second width different from the first width in the second direction;
N patterns arranged above the first standard cell according to the N-track structure;
M patterns arranged above the second standard cell according to the M-track structure; and
at least one jog pattern above the signal transfer filler cell, the at least one jog pattern connecting one pattern of the N patterns to one pattern of the M patterns,
wherein N and M are different positive integers of at least two.

12. The integrated circuit of claim 11, wherein:
the N patterns comprise unidirectional metal patterns,
the M patterns comprise unidirectional metal patterns, and
the at least one jog pattern includes a bidirectional metal pattern.

13. The integrated circuit of claim 11, wherein the N patterns are not aligned with the M patterns.

14. The integrated circuit of claim 11, wherein:
the N patterns comprise a first pattern and a second pattern, each extending in the first direction,
the M patterns comprise a third pattern and a fourth pattern, each extending in the first direction, and
the at least one jog pattern comprises:
a first jog pattern connecting the first pattern to the third pattern, and
a second jog pattern connecting the second pattern to the fourth pattern.

15. The integrated circuit of claim 11, wherein the first power rail, the second power rail, the N patterns, the M patterns, and the at least one jog pattern are arranged in a same layer.

16. An integrated circuit comprising:
a first standard cell group;
a second standard cell group spaced apart from the first standard cell group in a first direction; and
a signal transfer filler cell group between the first standard cell group and the second standard cell group,
wherein the first standard cell group comprises a plurality of first standard cells arranged in a second direction perpendicular to the first direction, each first standard cell comprising an N-track structure,
wherein the second standard cell group comprises a plurality of second standard cells arranged in the second direction, each second standard cell comprising an M-track structure,
wherein the signal transfer filler cell group comprises a plurality of signal transfer filler cells arranged in the second direction, each signal transfer filler cell comprising at least one jog pattern,
wherein the plurality of signal transfer filler cells each have a same shape, and
wherein N and M are positive integers of at least two.

17. The integrated circuit of claim 16, further comprising:
a plurality of first power rails respectively overlapping cell boundaries of the plurality of first standard cells, the plurality of first power rails extending in the first direction; and
a plurality of second power rails respectively overlapping cell boundaries of the plurality of second standard cells, the plurality of second power rails extending in the first direction,
wherein the plurality of first power rails and the plurality of second power rails have different widths in the second direction.

18. The integrated circuit of claim 16, further comprising:
N patterns arranged above one of the plurality of first standard cells according to the N-track structure; and
M patterns arranged above one of the plurality of second standard cells according to the M-track structure,
wherein the at least one jog pattern connects one of the N patterns to one of the M patterns.

19. The integrated circuit of claim 18, wherein:
the N patterns comprise unidirectional metal patterns,
the M patterns comprise unidirectional metal patterns, and
the at least one jog pattern comprises a bidirectional metal pattern.

20. The integrated circuit of claim 18, wherein:
the N patterns, the M patterns, and the at least one jog pattern are arranged in a same layer, and
the N patterns and the M patterns have different pitches.
